(19) United States
(12) Patent Application Publication
(10) Pub. No.: US 2014/0212671 A1
(43) Pub. Date: Jul. 31, 2014

(54) Direct Growth of Graphene by Molecular Beam Epitaxy for the Formation of Graphene Heterostructures

(71) Applicant: Jeffry Kelber, Denton, TX (US)

(72) Inventor: Jeffry Kelber, Denton, TX (US)

(21) Appl. No.: 14/232,652

(22) PCT Filed: Jul. 13, 2012
(86) PCT No.: PCT/US12/46621

§ 371 Date: Feb. 20, 2014

Related U.S. Application Data
(60) Provisional application No. 61/521,600, filed on Aug. 9, 2011.
(60) Provisional application No. 61/507,722, filed on Jul. 14, 2011.

(51) Int. Cl. C30B 23/06; H01L 43/10; C01B 31/04

(52) U.S. Cl. CPC C30B 23/066; C01B 31/0438; H01L 43/10
USPC 428/408; 117/108; 257/421

(57) ABSTRACT

Growth of single- and few-layer macroscopically continuous graphene films on Co₃O₄(111) by molecular beam epitaxy (MBE) has been characterized using low energy electron diffraction (LEED), Auger electron spectroscopy (AES) and x-ray photoelectron spectroscopy (XPS). MBE of Co on sapphire(0001) at 750 K followed by annealing in UHV (1000 K) results in ˜3 monolayers (ML) of Co₃O₄(111) due to O segregation from the bulk. Subsequent MBE of C at 1000 K from a graphite source yields a graphene LEED pattern incommensurate with that of the oxide, indicating graphene electronically decoupled from the oxide, as well as a sp² C(KVV) Auger lineshape, and π→π* C(1s) XPS satellite. The data strongly suggest the ability to grow graphene on other structurally similar magnetic/magnetoelecric oxides, such as Cr₂O₃(111)/Si for spintronic applications.

### PRIORITY DATA AND INCORPORATION BY REFERENCE

This application is a national stage application from PCT Patent Application Serial No. PCT/US12/46621, filed Jul. 13, 2012, which claims benefit of priority to U.S. Provisional Patent Application Ser. No. 61/507,722 filed Jul. 14, 2011, and U.S. Provisional Patent Application Ser. No. 61/521,600 filed Aug. 9, 2011 which is incorporated by reference in its entirety.

### BACKGROUND OF THE INVENTION

1. Field of the Invention

This application is directed to the direct growth of graphene layers on heterostructures and dielectric substrate surfaces for the purposes of forming logic devices and interconnects. This work was supported in part by Semiconductor Research Corporation, Task ID 2123.001.

2. Related Art

This case is generally related to the deposition of graphene on MgO surfaces, reported in U.S. patent application Ser. No. 12/980,767 and graphene on BN surfaces reported in U.S. Pat. No. 8,158,200. Both of these documents are incorporated herein-by-reference.

3. Background of the Technology

Graphene displays electronic properties, including high room temperature carrier mobilities, long carrier mean free paths, polarizeability in proximity to a magnetic substrate and long spin diffusion lengthswith exciting potential for charge or spin-based device applications. A critical step in practical device development, however, is the direct, controlled growth, by industrially feasible and scalable methods, of high quality single or few layer graphene films on dielectric substrates. Methods such as chemical or physical vapor deposition (CVD, PVD) or molecular beam epitaxy (MBE) are of interest, but must occur at growth temperatures allowing integration with Si CMOS or other device materials.

Direct growth of graphene on dielectric substrates by practical, scalable methods is accordingly essential for the industrial-scale production of graphene-based devices. To date, most reports have focused on graphene film growth by chemical vapor deposition on transition metals [1,2] followed by physical transfer, or by either high temperature decomposition [3-5] or by carbon MBE [6,7][8] on SiC(0001). The physical transfer approach poses significant problems for device integration, including the formation of nanoscale inhomogeneities [9,10], and SiO₂ phonon-induced limits on graphene carrier mobilities [11]. The integration of SiC with Si also poses significant issues. In contrast, the direct growth of graphene on metal oxides that could be formed on Si or on ferromagnetic substrates would enhance integration with Si CMOS at the front or back ends. Furthermore, the proximity of graphene layers to a high-k oxide substrate should significantly enhance graphene mobilities [12,13].

### SUMMARY OF THE INVENTION

Here we present LEED, Auger and XPS evidence of the formation of macroscopically continuous single- and few-layer graphene on Co₃O₄(111) thin films on Co(0001)/Al₂O₃(0001). We have previously demonstrated graphene growth by CVD or PVD on MgO(111) [14,15], which results in a ˜0.5-1 eV band gap, due to strong MgO/C(111) interfacial interactions—implying a commensurate MgO/graphene interface and extensive MgO(111) surface reconstruction [16]. In contrast to the MgO(111) results, growth of graphene on Co₃O₄(111) results in an incommensurate graphene/oxide interface, suggesting no band gap, but high mobilities due to electronic decoupling between oxide and graphene layers. Further, the use of MBE at 1000 K indicates no limit on the number of graphene layers that can be formed. Co₃O₄(111) is structurally similar to magnetoelectric Cr₂O₃(111), suggesting a variety of spintronic applications at the interconnect or device levels.

### BRIEF DESCRIPTION OF THE DRAWINGS

The accompanying drawings, which are incorporated herein and constitute part of this specification, illustrate exemplary embodiments of the invention, and, together with the general description given above and the detailed description given below, serve to explain the features of the invention.

FIG. 1 is AES data for MBE of C from a graphite rod source onto Co₃O₄(111)/Co(111). Dashed line—after ˜0.4 ML graphene; solid line—after ˜3 ML of graphene.

FIG. 2 is Plot of measured C(KVV) peak-to-peak height as a function of deposition time. Dashed lines are guides to the eye. Numbers above each data point correspond to calculated graphite overlayer thickness in monolayers.

FIG. 3 is LEED images and corresponding line scans for graphene MBE on Co₃O₄(111)/Co(0001)/Al₂O₃(0001). (a) 65 eV LEED image with ˜0.4 ML of carbon coverage (corresponding to AES scan, FIG. 1). (b) Corresponding line scan. Graphene-related peaks are labeled G1, G2, and oxide related peaks are labeled O1, O2. (c) LEED image after ˜3 ML carbon coverage (see again FIG. 1 for corresponding AES data). (d) Corresponding line scan. Note attenuation of the oxide-related LEED spots with increased carbon coverage.

FIG. 4 is XPS spectra of the ˜3ML graphene film on Co₃O₄(111)/Co(0001). (a) C(1s) with magnified view of the π→π* portion of the spectrum; (b) Co(2p) ; (c) O(1s).

### DETAILED DESCRIPTION

AES and LEED studies were carried out in a system described previously [17], but equipped with a commercially available multisource cell for electron beam-induced evaporation of Co and carbon from Co rod and graphite rod targets. The evaporator/sample distance was ˜9 cm. Co films ˜50 Å thick were deposited from a Co rod at 750 K onto 1 cm² Al₂O₃(0001) substrates. The base pressure in the chamber was ˜3×10⁻¹⁰ Torr, which increased during deposition to ˜5×10⁻⁹ Torr. Pressures remain below 1×10⁻⁸ throughout. Films were subsequently annealed in ultrahigh vacuum (UHV) to 1000 K, which allowed oxygen—dissolved in the Co film during deposition—to segregate to the surface and form a surface oxide film ˜3 ML thick, as determined by XPS (see below). Graphene films were deposited from a graphite rod with the sample at 1000 K. AES and LEED data were acquired after each deposition of carbon. XPS studies were carried out in a separate UHV chamber described previously [18], using a non-monochromatic MgKα x-ray source (15 kV, 300 W) and a hemispherical electron energy analyzer equipped with a channel plate detector and operating in fixed pass energy mode (23.5 eV). Average carbon overlayer thicknesses, and related analyses were determined from AES and XPS spectra according to standard methods [19]

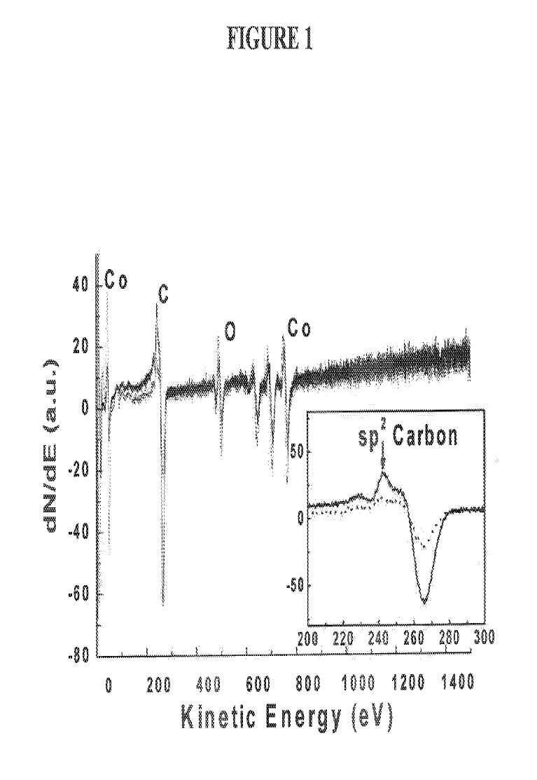

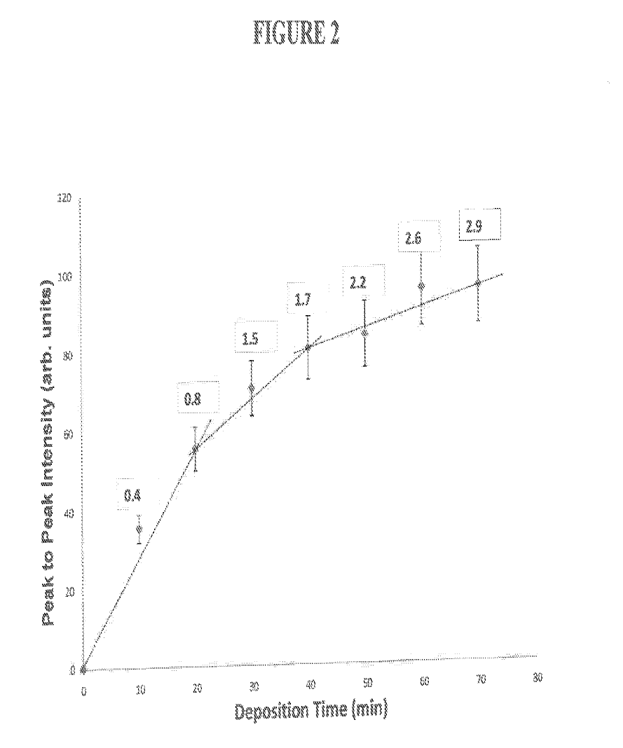

AES spectra are shown in FIG. 1 after the first carbon deposition, corresponding to an estimated average graphene thickness of 0.4 monolayers (ML), and after 7 total depositions, corresponding to ˜3 ML average thickness. The carbon C(KVV) lineshape is characteristic of sp² (graphitic) carbon [20]. Continued deposition of carbon at 1000 K resulted in monotonic decrease in the intensities of substrate-related Auger spectra (FIG. 1). Temperatures of about 800 K-1200 K are contemplated for this process. From the relative attenuations of the Co(MNN) and C(LMM) features (near 48 eV and 760 eV kinetic energy, respectively—FIG. 1) as a function of carbon deposition time, the increase in carbon overlayer thickness vs. deposition time can be estimated. This data is shown in FIG. 2. The data is well fit by a series of linear segments, with changes in slope corresponding to completion of a monolayer. This indicates that the graphene overlayers grow in a layer-by-layer manner [21]. Thus, the AES data (FIGS. 1 and 2) indicate continuous growth of carbon overlayers in a layer-by-layer manner by MBE at a substrate temperature of 1000 K.

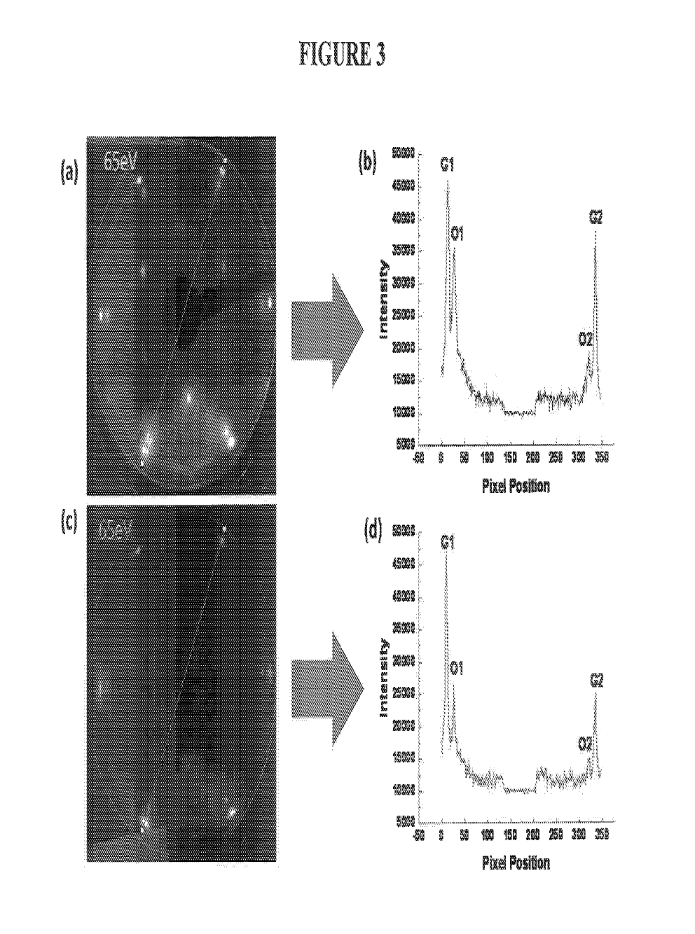

LEED images and corresponding line scans are displayed in FIG. 3. After deposition of ˜0.4 ML of carbon (FIG. 3a), the LEED image consists of an outer hexagonal array of bifurcated spots, and an inner hexagonal array, rotated 30° relative to the outer array. The graphene-related diffraction spots are the outermost spots in the bifurcated features (e.g., G1, G2; FIG. 3b), and these spots increase in intensity with additional carbon deposition, while the oxide related features (e.g., O1, O2, FIG. 3b,d and the innermost ring of spots, FIG. 3a,c) are progressively attenuated. The oxide lattice repeat distance corresponds to 2.8 Å, in good agreement with the oxygen-oxygen nearest neighbor distance at the Co₃O₄(111) surface [22]. This oxide pattern—an outer hexagonal array and inner R30 array with C_{3V} symmetry—corresponds closely to LEED spectra of few-layer Co₃O₄(111) on Al₂O₃(0001)[8]. A more complete LEED intensity analysis to determine the stacking relationship between graphene sheets is currently in progress, as are Raman studies to determine the defect (edge site) densities in the graphene sheets.

After AES and LEED analysis, the sample was exposed to ambient and then reinserted into the UHV chamber. No change was observed in either LEED or AES spectra, indicating that the graphene overlayers had inhibited additional oxidation or contamination of the ultrathin cobalt oxide film. This demonstrates the macroscopic continuity of the graphene overlayer, as even a continuous monolayer can inhibit the oxidation of reactive substrates (e.g., transition metals) upon exposure to ambient [17,23,24]. Following this experiment, the sample was again removed to ambient, and inserted into the XPS system.

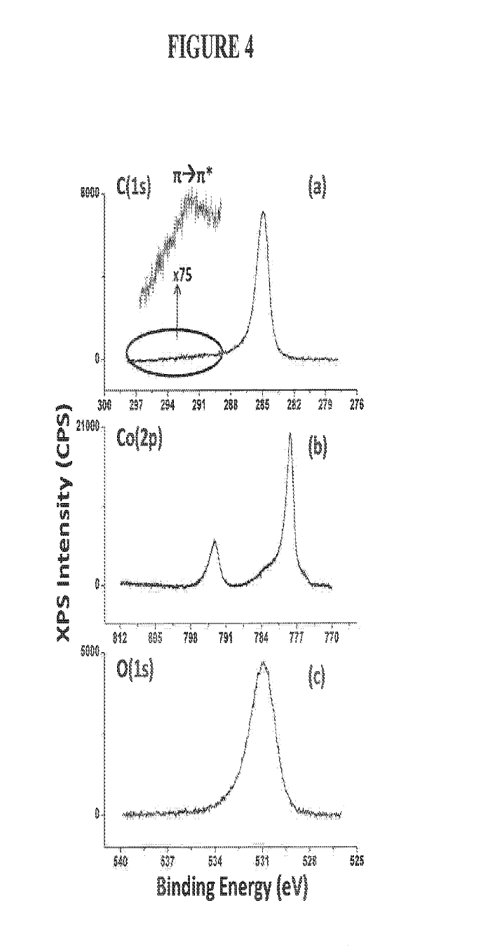

XPS core level spectra are displayed in FIG. 4. The C(1s) spectrum (FIG. 4a) shows a sharp feature with a maximum at 284.8 eV binding energy. The peak asymmetry is characteristic of graphene or graphite [7], and there is a clearly visible π→π* satellite peak (FIG. 4a, inset) which is indicative of sp² carbon. The peak maximum binding energy of 284.8 eV is slightly higher than the value of 284.5 eV typically reported for graphitic carbon [7], and this may reflect some graphene substrate charge transfer, as is frequently observed for metal overlayer formation on transition metal oxides. The Co(2p) spectrum (FIG. 4b) indicates the presence of ˜3 ML of Co in an oxidized state, on top of a thicker, metallic Co layer, consistent with the Auger spectra. The O(1s) spectrum has a peak maximum near 531 eV binding energy, and a shoulder at higher binding energy suggesting some oxide surface hydroxylation. The persistence of such hydroxylation in the presence of multilayer graphene growth is also consistent with an incommensurate graphene/oxide interface and resulting weak C—O interfacial chemical interactions.

### DISCUSSION

The data reported here demonstrate the formation of continuous layers of graphene on Co₃O₄(111)/Co(0001)/Al₂O₃(0001) by MBE at 1000 K. The LEED spectra (FIG. 3) indicate a lack of streaking, even in the multilayer stage, and this indicates that the graphene layers are azimuthally in registry with each other. This result is in direct contrast to multilayer graphene formation by Si evaporation from SiC(0001) [3], and also in contrast to the apparent streaking in LEED patterns upon the formation of single layer graphene by CVD on Co(0001)/Al₂O₃(0001)[25]. Thus, the AES (FIG. 1, 2) and LEED (FIG. 3) data are consistent with the formation of continuous graphene multilayers in registry with each other.

Additionally, the sharp LEED spots suggest large domain sizes. Raman spectroscopy and transport measurements are in progress.

The formation of well-ordered graphene overlayers by C MBE on Co₃O₄(111) at 1000 K is in significant contrast to C MBE on SiC(0001), where only amorphous carbon films are observed at deposition temperatures <1273 K [7]. This indicates that the initial interaction of carbon atoms with the substrate plays a critical role in the subsequent nucleation and growth of graphene or graphitic overlayers, and that such interactions are more conducive to carbon ordering on Co₃O₄(0001) than on either the Si or C-terminated face of SiC(0001). The observation of continuous graphene growth by MBE is also in contrast to recent findings [16] for graphene growth by magnetron sputter deposition at ambient temperature on MgO(111), followed by annealing at 1000 K in UHV to order the graphene film. The results on MgO(111) indicate a limiting graphene thickness of 2 ML by that method [16]. The results reported here suggest that C sputter deposition or MBE at elevated temperature on MgO(111) might well result in the ability to grow either single, or few graphene layers. Growth of up to three, four, five and even six- ten monolayers of graphene is contemplated by this method. The ability to grow graphene on MgO provides the ability to grow graphene on similar important metal oxides, including nickel oxide, cobalt oxide and chromium oxide.

Finally, the LEED data reported here (FIG. 3) conclusively demonstrate the formation of an incommensurate carbon/Co₃O₄ interface. This is in direct contrast to the commensurate interface indicated by photoemission, inverse photoemission and LEED measurements for graphene/MgO(111), where strong graphene-oxide interactions lead to a graphene band gap of ˜0.5-1 eV. Since the O—O nearest neighbor distance for both oxides is larger than the graphene lattice constant of 2.5 Å, the formation of a commensurate interface implies significant oxide reconstruction, which is commonly observed for the polar (111) surfaces of oxides with the rock-salt structure, such as MgO, NiO, or CoO [26,27]. The Co₃O₄ oxide, however, is in a sense already reconstructed CoO, where the instability inherent in a polar (111) surface has been reduced by the significant relaxation of Co and O ions in the surface layer [22]. While a graphene band gap is important for logic applications, the absence of a band gap, coupled with high carrier mobility, is important for various spintronics applications [28]. The structural similarity of Co₃O₄(111) to, e.g., Cr₂O₃(111) [22,29], combined with the magnetoelectric nature of Cr₂O₃(111) [30,31] and the magnetic polarizeability [32] and long spin diffusion lengths of graphene [28] suggest multiple voltage-controlled spintronics applications for graphene/oxide heterostructures.

Controlled growth of graphene on magnesium oxide, nickel oxide, cobalt oxide and chromium oxide, as well as other important metal oxides, is thus one aspect of this invention. These metal oxides are preferably formed on insulating substrates like Al₂O₃ and SiO₂. Insulating substrates of this type are commonly encountered in Si CMOS devices of a wide variety, and spintronic devices of high on/off rates.

Layer-by-layer growth of azimuthally-oriented graphene layers by C MBE at 1000 K on Co₃O₄(111) has been characterized by AES, LEED and XPS. The AES and XPS indicate macroscopically continuous ˜3 ML graphene (graphite) overlayer, which protects the substrate from further oxidation, even upon exposure to ambient. The AES and XPS data conclusively demonstrate sp² carbon hybridization, while LEED data indicate an incommensurate graphene/oxide interface, and highly ordered films as indicated by the sharp diffraction spots. The structural nature of the oxide, and the temperatures involved, are consistent with multiple device applications involving graphene/oxide heterostructures on Si substrates.

Bulk- or OH-terminated MgO(111) has a similar O—O nearest neighbor distance to Co₃O₄(111). Therefore, the difference between the incommensurate graphene/Co₃O₄)111 interface and the apparently commensurate graphene/MgO(111) interface is striking, and may reflect the tendency of highly polar (111) oxides with the rocksalt structure to reconstruct especially upon reaction with metal overlayers. In contrast, relaxations at the Co₃O₄(111) surface greatly reduce the surface polarity, and therefore the driving force for reconstruction. This in turn suggests that numerous metal oxides with similar O—O surface nearest neighbor distances and non-polar surface layers may serve as templates for graphene growth, with possibilities for numerous multifunctional charge- or spin-based devices. Additionally, highly (111)-oriented Co₃O₄ films have been grown on Si(100) by plasma-enhanced atomic layer deposition,^{[25]} suggesting a new pathway towards graphene integration with Si CMOS.

### REFERENCES

[1] X. Li, W. Cai, J. An, S. Kim, J. Nah, D. Yang, R. Piner, A. Velamakanni, I. Jung, E. Tutuc, S. K. Banerjee, L. Colobmo, R. S. Ruoff, Science 324 (2009) 1312.

[2] A. Reina, S. Thiele, X. Jia, S. Bhaviripudi, M. S. Dresselhaus, J. A. Schaefer, J. Kong, Nano. Res. 2 (2009) 509.

[3] W. A. de Heer, C. Berger, X. Wu, P. N. First, E. H. Conrad, X. Li, T. Li, M. Sprinkle, J. Hass, M. L. Sadowski, M. Potemski, G. Martinez, Sol. St. Commun 143 (2007) 92.

[4] C. Berger, Z. Spong, X. Li, X. Wu, N. Brown, C. Naud, D. Mayou, T. Li, J. Hass, A. Marchenkov N., E. H. Conrad, P. N. First, W. A. de Heer, Science 312 (2006) 1191.

[5] C. Berger, Z. Song, T. Li, Z. Li, A. Y. Ogbazghi, R. Feng, Z. Dai, A. N. Marchenkov, E. H. Congrad, P. N. First, W. A. de Heer, J. Phys. Chem. B 108 (2004) 19912.

[6] J. Park, W. C. Mitchel, L. Grazulis, H. E. Smith, K. G. Eyink, J. J. Boeckl, D. H. Tomich, S. D. Pacley, J. E. Hoelscher, Adv. Mat. 22 (2010) 4140.

[7] E. Moreau, F. J. Ferrer, D. Vignaud, S. Godey, X. Wallart, Phys. Stat. Solidi A 207 (2010) 300.

[8] C. A. F. Vaz, D. Prabhkaran, E. I. Altman, V. E. Henrich, Phys. Rev. B. 80 (2009) 155457.

[9] Parga, A. L. Vazquez de, F. Calleja, B. Borca, Passeggi Jr., M. C. G.:Hinarejos, J. J., F. Guineau, R. Miranda, Phys. Rev. Lett.100 (2008) 056807.

[10] Y. Zhang, V. W. Brar, C. Girit, A. Zettl, M. F. Crommie, Nature Phys. 5 (2009) 722.

[11] J. Chen, C. Jaong, S. Xiao, M. Ishigami, M. S. Fuhrer, Nature Nanotech. 3 (2008) 206.

[12] F. Chen, J. Xia, D. K. Ferry, N. Tao, Nano Lett. 9 (2009) 2571.

[13] R. S. Shishir and D. K. Ferry, J. Phys.: Cond. Matt. 21 (2009) 232204.

[14] L. Kong, C. Bjelkevig, S. Gaddam, M. Zhou, Y. H. Lee, G. H. Han, H. K. Jeong, N. Wu, Z. Zhang, J. Xiao, P. A. Dowben, J. A. Kelber, J. Phys. Chem. C. 114 (2010) 21618.

[15] S. Gaddam, C. Bjelkevig, S. Ge, K. Fukutani, P. A. Dowben, J. A. Kelber, J. Phys.: Cond. Matt. 23 (2011) 072204.

[16] J. A. Kelber, S. Gaddam, C. Vamala, S. Eswaran, P. A. Dowben, Proc. SPIE (in press) (2011)

[17] C. Bjelkevig, Z. Mi, J. Xiao, P. A. Dowben, L. Wang, W. Mei, J. A. Kelber, J. Phys.: Cond. Matt. 22 (2010) 302002.

[18] C. Bjelkevig and J. Kelber, Electrochim. Acta 54 (15) (2009) 3892.

[19] D. Briggs and M. P. Seah (editors) Practical Surface Analysis (2^{nd} edition) Vol. 1—Auger and X-ray Photoelectron Spectroscopy, J. Wiley and Sons, New York, N.Y. (1990).

[20] P. E. Viljoen, W. D. Roos, H. C. Swart, P. H. Holloway, Appl. Surf. Sci. 100/101 (1996) 612.

[21] C. Argile and G. E. Rhead, Surf Sci. Rep. 10 (1989) 277.

[22] W. Meyer, K. Biedermann, M. Gubo, L. Hammer, K. Heinz, J. Phys.: Cond. Matt. 20 (2008) 265011.

[23] Y. S. Dedkov, M. Fonin, U. Rudiger, C. Laubschat, Phys. Rev. Lett. 100 (2008) 107602.

[24] E. Kim, H. An, H. Jang, W. Cho, N. Lee, W. Lee, J. Jung, Chem. Vap. Dep. 17 (2011) 9.

[25] H. Ago, Y. Ito, N. Mizuta, K. Yoshida, B. Hu, C. M. Orofeo, M. Tsuji, K. Ikeda, S. Mizuno, ACS Nano 4 (2010) 7407.

[26] F. Rohr, K. Wirth, J. Libuda, D. Cappus, M. Baumer, H.- J. Freund, Surf Sci. 315 (1994) L977.

[27] V. K. Lazarov, R. Plass, H.-. Poon, D. K. Saldin, M. Weinert, S. A. Chambers, M. Gajdardziska-Josifovska, Phys. Rev. B 71 (2005) 115434.

[28] N. Tombros, C. Jozsa, M. Popinciuc, H. T. Jonkman, B. J. van Wees, Nature (2007) 571.

[29] D. Cappus, C. Xu, D. Ehrlich, B. Dillmann, C. A. Ventrice Jr., K. Al Shamery, H. Kuhlenbeck, H.-. Freund, Chem. Phys. 177 (1993) 533.

[30] S. Sahoo and C. Binek, Phil. Mag. Lett. 2007 (87) 259.

[31] N. Wu, X. He, A. L. Wysocki, U. Lanke, T. Komesu, K. D. Belashchenko, C. Binek, P. Dowben, Phys. Rev. Lett. 106 (2011) 087202.

[32] H. Haugen, D. Huertas-Hernando, A. Brataas, Phys. Rev. B 77 (2008) 115406.

While the present invention has been disclosed both generically, and with reference to specific alternatives, those alternatives are not intended to be limiting unless reflected in the claims set forth below. The invention is limited only by the provisions of the claims, and their equivalents, as would be recognized by one of skill in the art to which this application is directed.

What is claimed is:

1. A composition of matter comprising a substrate, a metal oxide formed on said substrate, and up to ten ML graphene formed on said metal oxide.

2. The composition of matter of claim 1, wherein said metal oxide is selected from the group consisting of cobalt oxide, chromium oxide, magnesium oxide and nickel oxide.

3. The composition of matter of claim 1, wherein said substrate is an insulating substrate.

4. The composition of matter of claim 3, wherein said substrate is comprised of Al₂O₃or SiO₂.

5. The composition of matter of claim 1, wherein said substrate is semiconductive.

6. The composition of matter of claim 5, wherein said substrate comprises silicon.

7. A semiconductor logic device, comprising a substrate, a metal oxide formed on said substrate and up to ten ML graphene formed on said metal oxide.

8. A spintronic device, comprising a substrate, a metal oxide formed on said substrate and up to ten ML graphene formed on said metal oxide.

9. The composition of matter of claim 1, wherein said graphene monolayers are continuous, well ordered and in registry with each other.

10. The composition of matter of claim 1, wherein said graphene lacks a significant band gap.

11. A method of controlled growth of graphene monolayers on a metal oxide surface, comprising depositing carbon on a surface of said metal oxide by molecular beam epitaxy of carbon for a period of time sufficient to grow said graphene monolayers.

12. The method of claim 11, wherein said molecular beam epitaxy employs a graphite rod as a carbon source.

13. The method of claim 11, wherein said molecular beam epitaxy is conducted under conditions of less than 1×10⁻⁸ Torr.

14. The method of claim 11, wherein said metal oxide is selected from the group consisting of cobalt oxide, chrome oxide, magnesium oxide and nickel oxide.

15. The method of claim 11, wherein said process is conducted at temperatures below about 1200° K.

16. The method of claim 15, wherein said method is conducted at temperatures of about 1000° K.

17. The method of claim 11, wherein said metal oxide is formed on a semiconductive surface.

18. The method of claim 11, wherein said metal oxide is formed on an insulating surface.
